(19) United States
(12) Patent Application Publication
(10) Pub. No.: US 2008/0024059 A1
(43) Pub. Date: Jan. 31, 2008

(54) SYSTEM FOR DISPLAYING IMAGES INCLUIDNG ELECTROLUMINESCENT DEVICE AND METHOD FOR FABRICATING THE SAME

(75) Inventor: Hsiang-Lun Hsu, Miaoli County (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: TPO DISPLAYS CORP., Miao-Li County (TW)

(21) Appl. No.: 11/460,297

(22) Filed: Jul. 27, 2006

(51) Int. Cl. H01L 51/54

(52) U.S. Cl. 313/506; 428/690; 428/917

(57) ABSTRACT

Systems for displaying images are provided. An exemplary system comprises an organic electroluminescent device, comprising a substrate, an anode formed on the substrate, a plurality of electroluminescent layers formed on the anode, an electron injection layer formed on the electroluminescent layers, and a cathode formed directly on the electron injection layer. The electron injection layer comprises a conductive material and a lanthanide-containing compound, an actinide-containing compound, or a fluorine-containing compound doped in the conductive material.

### BACKGROUND OF THE INVENTION

1. Field of the Invention

The present invention relates to an electroluminescent device and a method for fabricating the same and, more particularly, to an electroluminescent device having improved injection electron efficiency from a cathode to electroluminescent layers and fabrication method thereof.

2. Description of the Related Art

Recently, with the development and wide application of electronic products such as mobile phones, personal digital assistants, and notebook computers, there has been an increased demand for flat display devices which consume less power and occupy less space. Organic electroluminescent devices are self-emitting and highly luminous, have a wider viewing angle, faster response, and a simple fabrication process, making them an industry display of choice.

As shown in FIG. 1, an organic electroluminescent device 10 is basically configured such that an anode 14 is formed on a substrate 12, and a hole transport layer 16, an emitter layer 18, an electron transport layer 20, and a cathode 22 are sequentially stacked on the anode 14. Here, the hole transport layer 16, the emission layer 18 and the electron transport layer 20 are organic layers made of organic materials.

In an organic electroluminescent device, electrons are propelled from the cathode and holes from the anode, and the applied electric field induces a potential difference, such that the electrons and holes move and centralize in the emission layer via the electron or hole transport layer respectively, resulting in luminescence through recombination thereof. The recombination takes place within the emission layer at a region near the interface between the emission layer and the hole transport layer (or the electron transport layer) to generate excitons. The generated excitons de-excite from an excited state to a ground state to emit light, thus forming an image.

In order to improve a low driving voltage characteristic and charge balance between electrons and holes, it is necessary to increase efficiency in injecting electrons from the cathode into the electron transport layer. Conventional methods for increasing such injection efficiency have been proposed in U.S. Pat. Nos. 5,429,884, 5,059,862 and 4,885,211, describing use of an alkali metal having a low work function, e.g., lithium or magnesium, codeposition of an alkali metal and a metal such as aluminum or silver, and use of alloys of an alkali metal and a metal such as aluminum or silver, respectively. Metal with a low work function is very unstable and highly reactive. Thus, its use is disadvantageous in view of the processability and the stability of EL device.

Other techniques for increasing the electron injection efficiency have been proposed in U.S. Pat. Nos. 5,776,622, 5,776,623, 5,937,272 and 5,739,635, and Appl. Phy Lett. 73 (1998) P. 1185, in which an electron injection layer containing inorganic materials such as LiF, CsF, SrO or Li₂O, is formed between the cathode and the electron transport layer with a thickness of 5˜20 Å.

Recently, another method for increasing electron injection efficiency has been proposed in which a metal alkylate or metal arylate, such as CH₃COOLᵢ or C₆H₅COOLᵢ, is formed between the cathode and the electron transport layer. This method is also problematic in that it is difficult to form a thin film having a uniform thickness of 5˜40 Å, which is not suitable for large-area deposition.

Thus, in order to enhance luminescent efficiency, an active matrix organic electroluminescent device having improved injection electron efficiency from a cathode to electroluminescent layers is called for.

### BRIEF SUMMARY OF THE INVENTION

Systems for displaying images are provided. An exemplary embodiment of a system comprises an organic electroluminescent device, having a substrate, an anode formed on the substrate, a plurality of electroluminescent layers formed on the anode, an electron injection layer formed on the electroluminescent layers, and a cathode formed directly on the electron injection layer. The electron injection layer comprises a conductive material and a lanthanide-containing compound, an actinide-containing compound, or a fluorine-containing compound doped in the conductive material.

According to another embodiment of the invention, the system comprises an electroluminescent device, having a substrate, an anode formed on the substrate, electroluminescent layers formed on the anode, and a doped cathode formed on the electroluminescent layers, wherein the doped cathode comprises a conductive material and a lanthanide-containing compound, an actinide-containing compound, or a fluorine-containing compound doped in the conductive material.

Methods for fabricating systems for displaying images are also provided. In an exemplary embodiment of a method for fabricating systems for displaying images, a substrate is provided. An anode, electroluminescent layers, an electron injection layer, and a cathode are sequentially formed on the substrate, wherein the electron injection layer comprises a conductive material and a lanthanide-containing compound, an actinide-containing compound, or a fluorine-containing compound doped in the conductive material. The electron injection layer is directly formed on the cathode.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a cross section of a conventional electroluminescent device.

FIG. 2 shows a cross section of an embodiment of an electroluminescent device.

FIG. 3 shows a cross section of another embodiment of an electroluminescent device.

FIG. 4 shows a graph plotting operating voltage against current density of the electroluminescent devices as disclosed in Examples 1˜4.

FIG. 5 shows a graph plotting operating voltage against brightness of the electroluminescent devices as disclosed in Examples 1˜4.

FIG. 6 shows a graph plotting current density against efficiency of the electroluminescent devices as disclosed in Examples 1˜4.

FIG. 7 shows a graph plotting operating voltage against current density of the electroluminescent devices as disclosed in Example 1 and Comparative Example 1.

FIG. 8 shows a graph plotting operating voltage against brightness of the electroluminescent devices as disclosed in Example 1 and Comparative Example 1.

FIG. 9 shows a graph plotting current density against efficiency of the electroluminescent devices as disclosed in Example 1 and Comparative Example 1.

FIG. 10a and 10b show cross sections of some embodiments of electroluminescent devices of the invention.

FIG. 11 schematically shows another embodiment of a system for displaying images.

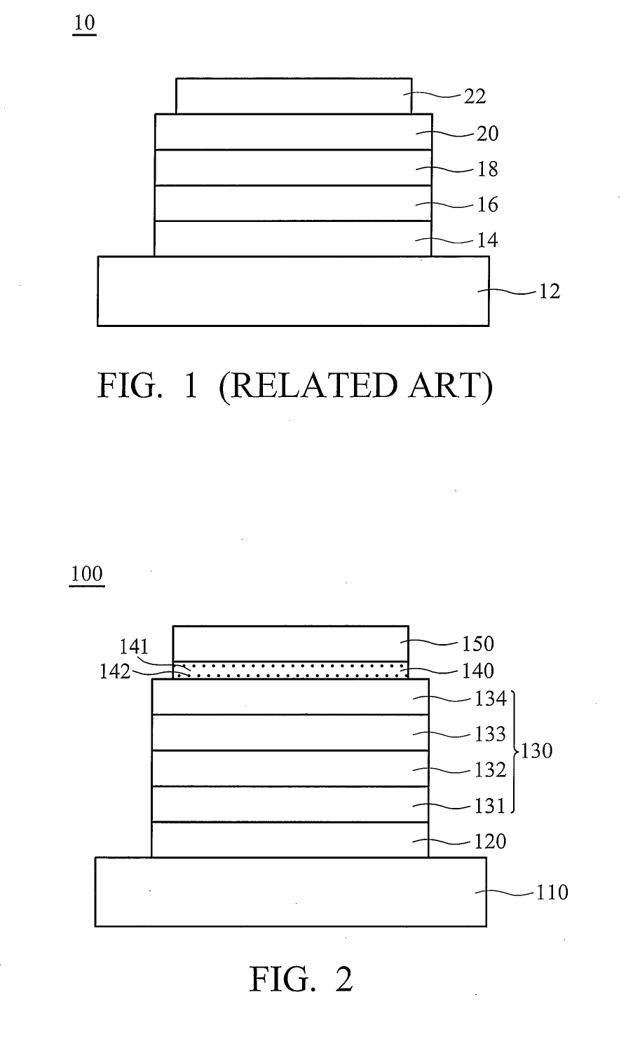

### DETAILED DESCRIPTION OF THE INVENTION

The invention uses an electron injection layer to facilitate injection of electrons into electroluminescent layers from a cathode.

FIG. 2 shows an embodiment of a system for displaying images that includes an electroluminescent device 100. In one embodiment, the electroluminescent device 100 comprises a substrate 110, an anode 120, electroluminescent layers 130, an electron injection layer 140, and a cathode 150, as shown in FIG. 2. The substrate 110 can be glass or plastic. Suitable material for the anode 120 is transparent metal or metal oxide, such as indium tin oxide (ITO), indium zinc oxide (IZO), aluminum zinc oxide (AZO), or zinc oxide (ZnO), formed by sputtering, electron beam evaporation, thermal evaporation, or chemical vapor deposition.

The electroluminescent layers 130 may comprise a hole injection layer 131, a hole transport layer 132, an emission layer 133, and an electron transport layer 134, including organic semiconductor materials, such as small molecule materials, polymer, or organometallic complex, formed by thermal vacuum evaporation, spin coating, dip coating, roll-coating, injection-filling, embossing, stamping, physical vapor deposition, or chemical vapor deposition. The thickness of each layer is not particularly limited, but if too thick, a large applied voltage is required to obtain a fixed light output, thus reducing efficiency. On the other hand, if it is too thin, pin-holes are generated. The thickness of each of the layers 131, 132, 133, and 134 is preferably of 1 nm to 1 μm.

Particularly, the electron injection layer 140 comprises a conductive material 141 and a lanthanide-containing compound, an actinide-containing compound, or a fluorine-containing compound 142, wherein the lanthanide-containing, actinide-containing compound, or fluorine-containing compound 142, serving as a dopant, is doped in the conductive material 141. The electron injection layer 140 is formed between the electroluminescent layers 130 and the cathode 150, and can be 0.1˜50 nm thick, preferably 1˜30 nm thick. The actinide-containing compound may comprise actinide fluoride, actinide chloride, actinide bromide, actinide oxide, actinide nitride, actinide sulfide, actinide carbonate, or combinations thereof, and the lanthanide-containing compound may comprise lanthanide fluoride, lanthanide chloride, lanthanide bromide, lanthanide oxide, lanthanide nitride, lanthanide sulfide, lanthanide carbonate, or combinations thereof. Further, the fluorine-containing compound can comprise LiF. Wherein, the lanthanide or actinide element may be selected from the group of elements consisting of Ce, Pr, Nd, Sm, Eu, Gd, Tb, Dy, Ho, Er, Tm, Yb, Lu, and U. For example, the electron injection layer 140 can comprise cerium halide (such as CeF₃ or CeF₄), cerium nitride, cerium oxide, cerium sulfide, cerium oxyfluoride, cerium carbonate, or combinations thereof. The conductive material can comprise indium tin oxide (ITO), indium zinc oxide (IZO), aluminum zinc oxide (AZO), zinc oxide (ZnO), Ca, Ag, Mg, Al, Li, or combinations thereof. Note that the weight ratio between the conductive material and the lanthanide-containing, actinide-containing compound, or fluorine-containing compound is 10:1-200:1, preferably 20:1˜200:1.

The cathode 150 can be capable of injecting electrons into the electroluminescent layer 130 via the electron injection layer 140, for example, a low work function material such as Ca, Ag, Mg, Al, Li, or alloys thereof, formed by sputtering, electron beam evaporation, thermal evaporation, or chemical vapor deposition. In an embodiment of the invention, the material of the cathode 150 can be the same or different with the conductive material 141.

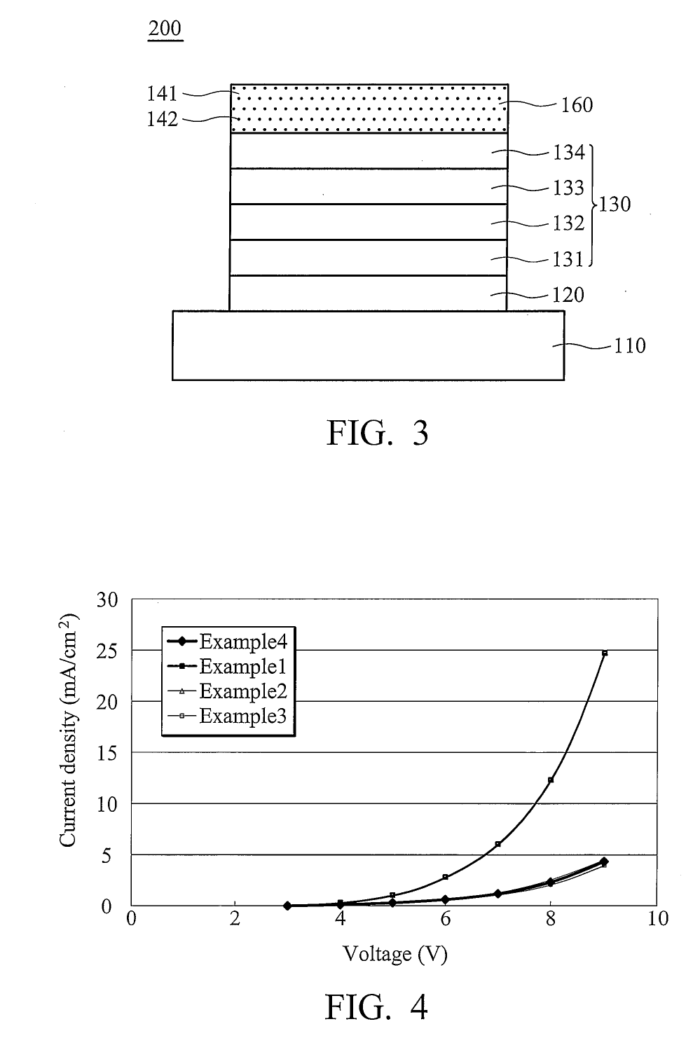

Referring to FIG. 3, in the electroluminescent device 200 according to another embodiment of the invention, since the cathode can have the same composition as the electron injection layer, the cathode and the electron injection layer can combine together to be a doped cathode 160. The doped cathode 160 comprises a conductive material 141 and a lanthanide-containing compound, an actinide-containing compound, or a fluorine-containing compound 142. The lanthanide-containing, actinide-containing compound, or fluorine-containing compound 142 serves as a dopant and is doped in the conductive material 141.

The following examples are intended to illustrate the invention more fully without limiting their scope, since numerous modifications and variations will be apparent to those skilled in this art.

### EXAMPLE 1

A glass substrate with an indium tin oxide (ITO) film of 100 nm was provided and then washed with a cleaning agent, acetone, and isopropanol with ultrasonic agitation. After drying with nitrogen flow, the ITO film was subjected to uv/ozone treatment. Next, a hole transport layer, light-emitting layer, electron transport layer, electron injection layer, and cathode were subsequently formed on the ITO film at 10⁻⁵ Pa, obtaining the electroluminescent device (1). The materials and layers formed therefrom are described in the following.

The hole transport layer, with a thickness of 150 nm, consisting of NPB (N,N′-di-1-naphthyl-N,N′-diphenyl-1,1′-biphenyl-1,1′-biphenyl-4,4′-diamine). The light-emitting layer 18, with a thickness of 40 nm, consisting of C545T (10-(2-Benzothiazolyl)-2,3,6,7-tetrahydro-1,1,7,7-tetramethyl-1H,5H,11H-(1)-benzopyropyrano(6,7-8-i,j)quinolizin-11-one) as dopant, and Alq₃ (tris (8-hydroxyquinoline) aluminum) as light-emitting material host, wherein the weight ratio between Alq₃ and dopant was 100:1. The electron transport layer, with a thickness of 10 nm, consisting of Alq₃ (tris (8-hydroxyquinoline) aluminum). The electron injection layer, with a thickness of 20 nm, consisting of Al as conductive material and cerium fluoride (CeF₄) as dopant, wherein the weight ratio between Al and CeF₄ was 20:1. The cathode, with a thickness of 130 mn, consisting of Al.

The emissive structure of the electroluminescent device (1) can be represented as below:

ITO 100 nm/NPB 150 nm/Alq₃:C545T 100:1 40 nm/Alq₃ 10 mn/Al:CeF₄ 20:1 20 nm/Al 130 nm

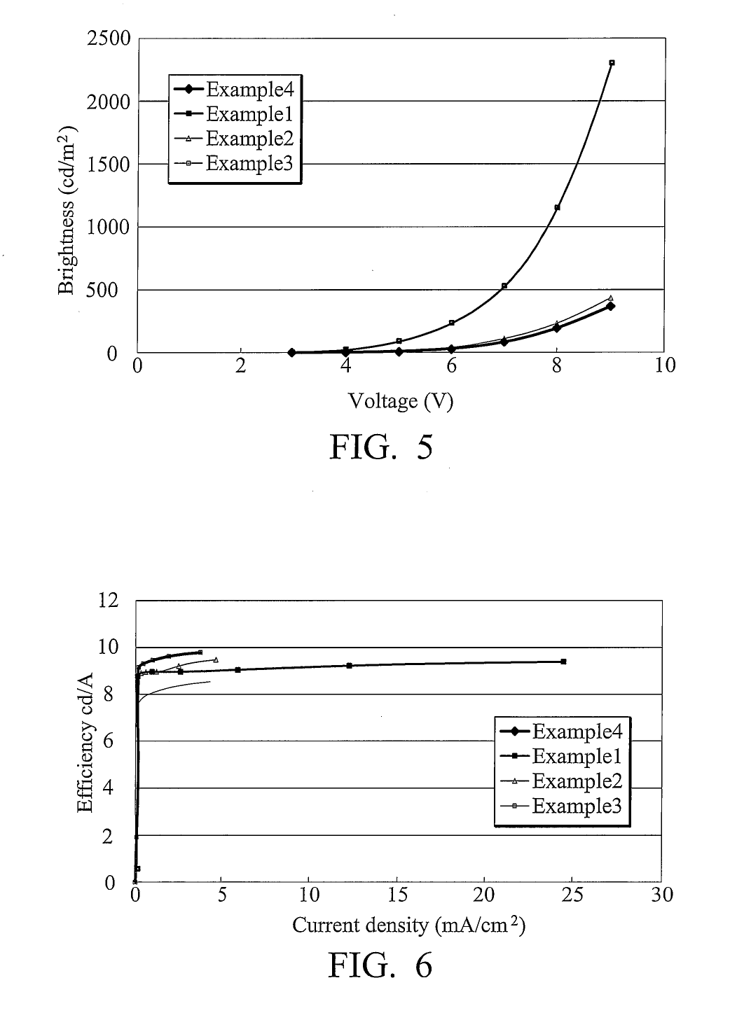

The optical property of electroluminescent device (1), as described in Example 1, was measured by PR650 (purchased from Photo Research Inc.) and Minolta TS110. The result is shown in FIGS. 4, 5, and 6.

### EXAMPLES2˜3

Examples 2 and 3 were performed the same as Example 1 except that the weight ratio between Al and CeF₄ was changed to 40:1 and 200:1 respectively, yielding electroluminescent devices (2) and (3).

The optical property of electroluminescent devices (2) and (3), as described respectively in Examples 2 and 3, were measured by PR650 (purchased from Photo Research Inc.) and Minolta TS110. The result was shown in FIGS. 4, 5, and 6.

### EXAMPLE 4

Example 4 was performed as Example 1 excepting for substitution of LiF for CeF₄. The structure of the obtained electroluminescent device (4) can be represented as below:

ITO 100 nm/NPB 150 nm/Alq₃:C545T 100:1 40 nm/Alq₃ 10 nm/Al:LiF 20:1 20 nm/Al 130 nm

FIGS. 4, 5, and 6 illustrate the differences between properties for the electroluminescent devices (1)-(4) as described respectively in Examples 1˜4. In FIGS. 4, 5, and 6, the electroluminescent device (1) disclosed in Example 1, having an electron injection layer consisting of Al and CeF₄ with a weight ratio of 20:1, has lower operating voltages and higher performance.

### COMPARATIVE EXAMPLE 1

A glass substrate with an indium tin oxide (ITO) film of 100 nm was provided and then washed with a cleaning agent, acetone, and isopropanol with ultrasonic agitation. After drying with nitrogen flow, the ITO film was subjected to uv/ozone treatment. Next, a hole transport layer with a thickness of 150 nm, consisting of NPB, was formed on the ITO film. Next, a light-emitting layer with a thickness of 40 nm, consisting of C545T and Alq₃, was formed on the hole transport layer, wherein the weight ratio between Alq₃ and C545T was 100:1. Next, an electron transport layer with a thickness of 10 nm, consisting of Alq₃ was formed on the light-emitting layer. Next, a LiF layer with a thickness of 1 nm was formed on the light-emitting layer. Finally, an aluminum electrode with a thickness of 150 nm was formed on the LiF layer, yielding the electroluminescent device (5).

The structure of the obtained electroluminescent device (5) can be represented as below:

ITO 100 nm/NPB 150 nm/Alq₃:C545T 100:1 40 nm/Alq₃ 10 nm/LiF 1 nm/Al 150 nm

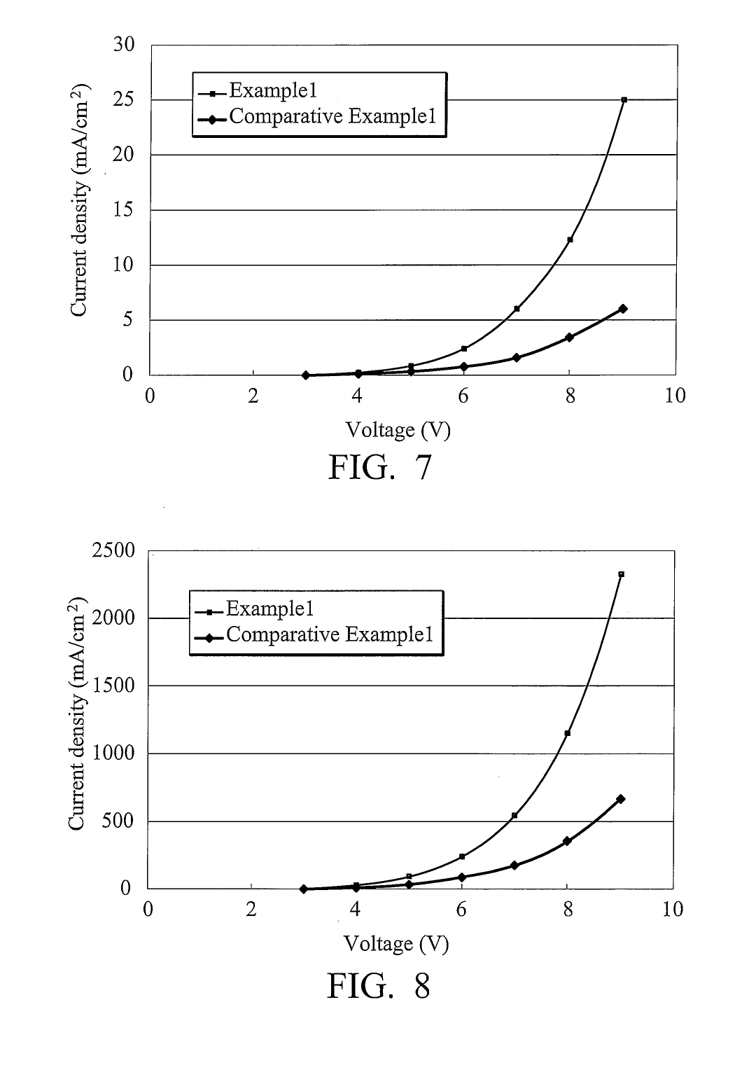

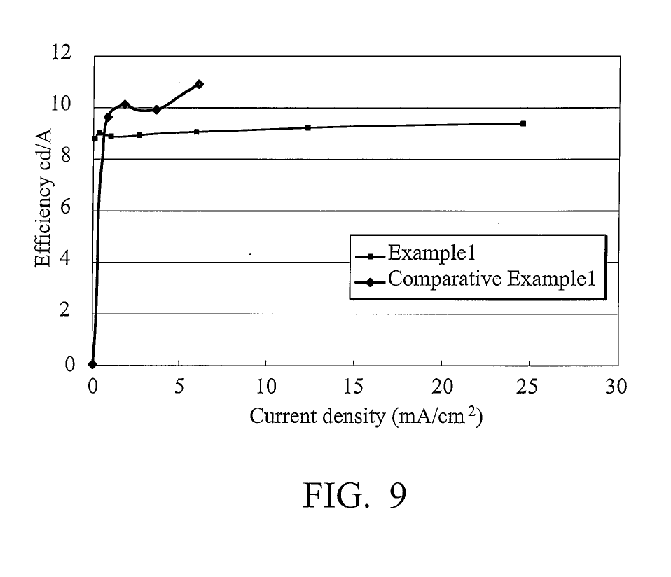

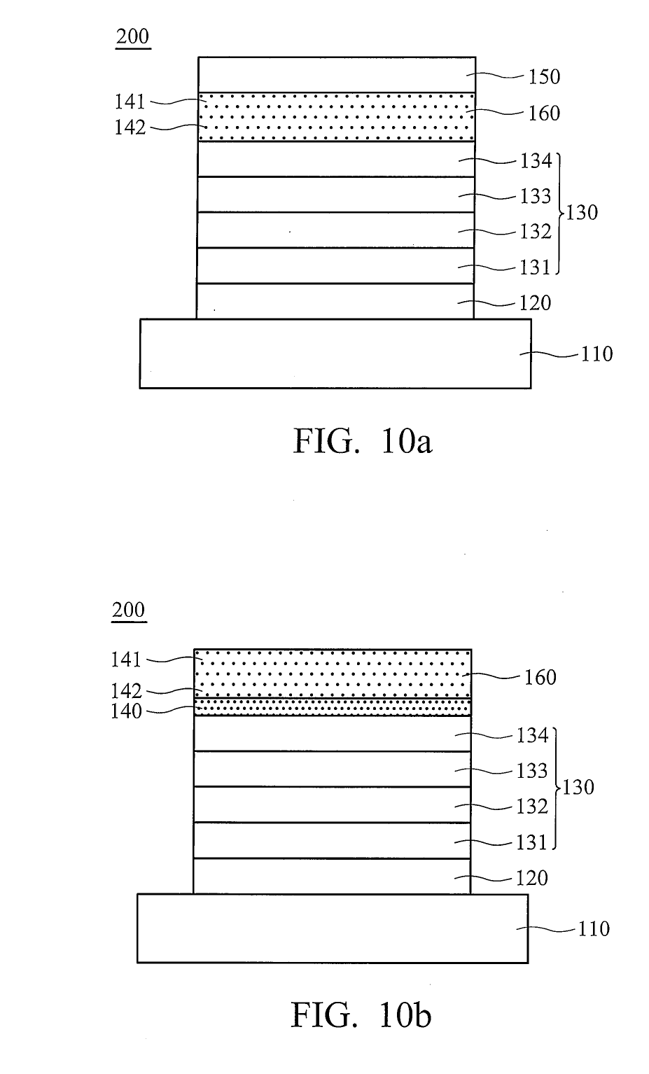

FIGS. 7, 8, and 9 illustrate the differences between properties of the electroluminescent devices (1) and (5) as described respectively in Example 1 and Comparative Example 1. Accordingly, the electroluminescent device (1), having an electron injection layer consisting of Al and CeF₄ with a weight ratio of 20:1, disclosed in Example 1 has lower operating voltage and higher performance.

In embodiments as shown in FIG. 3, the electroluminescent device 200 can further comprises a cathode layer 150 formed on the doped cathode 160, as shown in FIG. 10a. The cathode 150 can be a low work function material such as Ca, Ag, Mg, Al, Li, or alloys thereof, formed by sputtering, electron beam evaporation, thermal evaporation, or chemical vapor deposition. In an embodiment of the invention, the material of the cathode 150 can be the same or different with the conductive material 141.

Moreover, referring to FIG. 10b, the electroluminescent device 200 can comprises the electron injection layer 140 of the invention, formed between the doped cathode 160 and the electroluminescent layers 130.

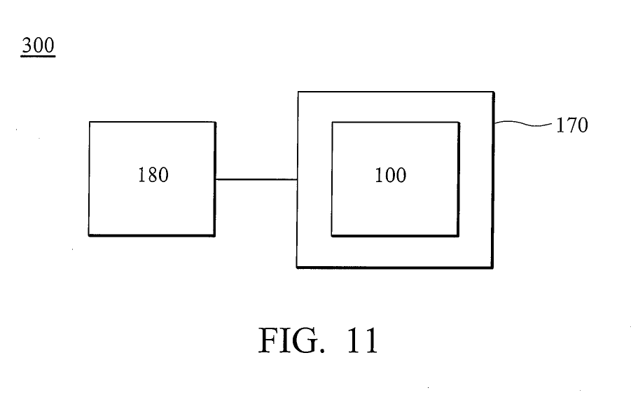

FIG. 11 schematically shows an embodiment of a system for displaying images which, in this case, is implemented as a display device 170 or an electronic device 300. The described organic electroluminescent device 100 can be incorporated into a display panel that can be an OLED panel. As shown in FIG. 11, the display panel 170 comprises an electroluminescent device, such as the electroluminescent device 100 shown in FIG. 2. The display panel 170 can be employed in a variety of electronic devices. Generally, the system for displaying images, such as electronic device 300, can comprise the display panel 170 and an input unit 180. Further, the input unit 180 is operatively coupled to the display panel 170 and provides input signals (e.g., an image signal) to the display panel 170 to generate images. The electronic device 300 can be a mobile phone, digital camera, personal digital assistant, notebook computer, desktop computer, television, car display, or portable DVD player, for example.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
an electroluminescent device, comprising:
a substrate;
an anode formed on the substrate;
electroluminescent layers formed on the anode;
an electron injection layer formed on the electroluminescent layers, wherein the electron injection layer comprises a conductive material and a lanthanide-containing compound, an actinide-containing compound, or a fluorine-containing compound doped in the conductive material; and
a cathode formed directly on the electron injection layer.

2. The system as claimed in claim 1, wherein the electron injection layer has a thickness of 0.1˜50 nm.

3. The system as claimed in claim 1, wherein the electroluminescent layers comprise a hole transport layer, an emission layer, and an electron transport layer.

4. The system as claimed in claim 3, wherein the electron injection layer is formed between the electron transport layer and the cathode.

5. The system as claimed in claim 1, wherein the actinide-containing compound comprises actinide fluoride, actinide chloride, actinide bromide, actinide oxide, actinide nitride, actinide sulfide, actinide carbonate, or combinations thereof.

6. The system as claimed in claim 1, wherein the lanthanide-containing compound comprises lanthanide fluoride, lanthanide chloride, lanthanide bromide, lanthanide oxide, lanthanide nitride, lanthanide sulfide, lanthanide carbonate, or combinations thereof.

7. The system as claimed in claim 1, wherein the lanthanide-containing compound comprises cerium halide, cerium nitride, cerium oxide, cerium sulfide, cerium oxyfluoride, cerium carbonate, or combinations thereof.

8. The system as claimed in claim 1, wherein the lanthanide-containing compound comprises CeF₃, CeF₄, or combinations thereof.

9. The system as claimed in claim 1, wherein the conductive material comprises indium tin oxide (ITO), indium zinc oxide (IZO), aluminum zinc oxide (AZO), zinc oxide (ZnO), Ca, Ag, Mg, Al, Li, or combinations thereof.

10. The system as claimed in claim 1, wherein the weight ratio between the conductive material and the lanthanide-containing, actinide-containing compound, or fluorine-containing compound is 10:1˜200:1.

11. The system as claimed in claim 1, wherein the cathode has the same composition of the electron injection layer.

12. The system as claimed in claim 1, further comprising a display panel, wherein the electroluminescent device forms a portion of the display panel.

13. The system as claimed in claim 12, further comprising an electronic device, wherein the electronic device comprises:
the display panel; and
an input unit coupled to the display panel and operative to provide input to the display panel such that the display panel displays images.

14. The system as claimed in claim 13, wherein the electronic device is a mobile phone, digital camera, PDA (personal digital assistant), notebook computer, desktop computer, television, car display, or portable DVD player.

15. A system for displaying images, comprising:
an electroluminescent device, comprising:
a substrate;
an anode formed on the substrate;
electroluminescent layers formed on the anode; and
a doped cathode formed on the electroluminescent layers, wherein the doped cathode comprises a conductive material and a lanthanide-containing compound, an actinide-containing compound, or a fluorine-containing compound doped in the conductive material.

16. The system as claimed in claim 15, further comprising a cathode formed on the doped cathode.

17. The system as claimed in claim 15, further comprising an electron injection layer formed between the electroluminescent layers and the doped cathode.
